(19) United States
(12) Patent Application Publication
(10) Pub. No.: US 2004/0137679 A1
(43) Pub. Date: Jul. 15, 2004

(54) Method for fabricating capacitor in semiconductor device

(76) Inventor: Sang-Deok Kim, Ichon-shi (KR)

Correspondence Address: BLAKELY SOKOLOFF TAYLOR & ZAFMAN, 12400 WILSHIRE BOULEVARD, SEVENTH FLOOR, LOS ANGELES, CA, 90025, US

(21) Appl. No.: 10/621,185

(22) Filed: Jul. 15, 2003

(30) Foreign Application Priority Data
Dec. 30, 2002 (KR) 2002-86253

(51) Int. Cl. H01L 21/8234; H01L 21/8244; H01L 21/8242; H01L 21/20

(52) U.S. Cl. 438/253; 438/396

(57) ABSTRACT

The present invention provides a method of fabricating a capacitor for improving the shape of a bottom electrode by using a sacrificial layer at a producing process. For this object, the method for fabricating the capacitor for a semiconductor device includes the step of: forming a sacrificial layer in the height of capacitor on the substrate so that a etch rate becomes lower if it's height becomes higher; forming a trench by selectively eliminating the sacrifice layer in manner of wet etch process; forming a bottom electrode in the trench; eliminating the sacrificial layer; forming a dielectric thin film on the bottom electrode; and forming the top electrode on the dielectric thin film.

### FIELD OF INVENTION

The present invention relates to a method for manufacturing a semiconductor device; and, more particularly, to fabricate a capacitor in the semiconductor memory device.

### DESCRIPTION OF RELATED ART

According to higher integration of semiconductor devices, e.g., a dynamic random access memory DRAM, a total area of a memory cell for storing information is rapidly decreased.

The decrease of the memory cell area occurs to reduce an area of a capacitor in the memory cell. In addition, it occurs not only to drop a sensing margin and a sensing speed but also to have the problem with declining durability against a soft error generated by a particle.

A capacitance C of the capacitor is defined by the following equation.

C=ε×As/d (Eq. 1)

Herein, ε is a permittivity; As is an active surface area of a electrode; d is a distance between the electrodes.

Thus, there are three manners for increasing capacitance of the capacitor: first manner to broaden the active surface area of the electrode; second manner to decrease a thickness of a dielectric substance; and third manner to increase the permittivity.

In the above three ways, first of all, there has been considered the first alternative which is used to broaden the active surface area of the electrode. So, there should be provided the capacitor which has a three-dimensional structure like a concave structure, a cylinder structure, a multi-layer pin structure, and so on for broadening the active surface area of the electrode in restricted layout area.

FIGS. 1A to 1B are sectional views presenting a conventional method of fabricating a cylinder type capacitor.

As shown in FIG. 1A, an inter-insulation layer 12 is formed on a substrate 10 including an active area 11. The contact trench coupled to the active area of the substrate 10 is formed by penetrating the inter-insulation layer 12. The contact plug 13 is formed by recovering a conductive material. A sacrificial layer 14 is formed in size of the capacitor to be formed. A capacitor trench 15 is formed by selectively eliminating the sacrificial layer 14 in area which the capacitor will be deposited on. The sacrificial layer 14 functions a mold in process that forms a following bottom electrode.

As shown in FIG. 1B, the sacrificial layer 14 is eliminated by using a wet-etching process. Then, a thin dielectric film 17 is formed on a bottom electrode 16 and a top electrode 18 is formed on the thin dielectric film 17.

Because of higher implementation of the semiconductor device, there is decreased the area in which the capacitor is formed. However, a predetermined capacitance is needed for stable operation of the semiconductor device. So, as described above, the bottom electrode of the semiconductor device is formed in shape of a cylinder for increasing surface area.

As a result, the area in which the capacitor is formed is decreased but height of the capacitor is heightened. So, it is difficult to form the stable bottom electrode and especially there is occurred some critical problem because of neighboring bottom electrodes which are connected to each other.

In addition, because cylinder type capacitor can use at inside and outside of the bottom electrode, the area in which a charge is stored broaden twice and the predetermined capacitance is easily obtained. However, at removing the sacrificial layer 14 for making the outside of the bottom electrode usable, the capacitor may be connected to another capacitor because of an insufficient space of the bottom electrode.

FIG. 2 is an exemplary diagram of an electron microscope photo showing a problem in fabricating the conventional capacitor in accordance with the prior art.

As shown, when the sacrifice layer is removed after the bottom electrode is formed inside the trench, an error is occurred because of connecting the bottom electrodes to each other. (referred as A area)

For solving above problem, there is provided a method for forming lower side of the bottom electrode to be wider than upper side of the bottom electrode in the cylinder type capacitor.

FIG. 3A and FIG. 3B are a sectional views presenting another conventional method for fabricating the cylinder type capacitor.

As shown in FIG. 3A, the inter-insulation film 12 is formed on the substrate 10 where the active area 11 is formed. The contact trench is formed to connect to the active area 11 in the substrate 10 by penetrating the inter-insulation film 12. The contact plug 13 is formed by filling the conductive material. Then, the first and second sacrifice films 19 and 20 are formed in size of the capacitor. The first sacrificial film 19 is made of a phosphor-silicate glass layer (hereinafter, referred as PSG), and the second sacrificial film for capacitor 20 is made of the tetraethylorthosilicate layer (hereinafter, referred as TEOS).

The trench 21 is formed to expose the contact plug 13 by selectively etching the first and second sacrificial films 19 and 20. The lower part of the hole for capacitor 21 is formed wider than its upper part because the TEOS layer is lower of the wet etching ratio than the PSG layer.

The trench 21 is formed by either wet etching process once or additionally etching the second sacrifice layer 20 in the manner of wet etching process, after the first and the second sacrifice layer 19 and 20 are selectively etched in the manner of dry etching process.

Then, the bottom electrode 22 is formed inside the trench for capacitor 21.

As shown in FIG. 3B, the first and second sacrifice layers 19 and 20 are eliminated. The dielectric thin layer 23 is formed on the bottom electrode 22. The top electrode 24 is formed on the dielectric thin layer 23.

FIG. 4A is a diagram of electron microscope photos showing a cross section of the trench inside the conventional capacitor in accordance with the prior art, and FIG. 4B describes the lower part of the trench shown in FIG. 4A by zooming in the Fig.

As shown in FIG. 4B, the trench is formed widely in the PSG layer and narrowly in the TEOS layer.

However, if the capacitor is formed in the above manner, there are needed a lot of the process because the two sacrificial layers are formed.

In addition, because the PSG layer used as the first sacrifice layer has a characteristic of absorbing water, there is pointed the problem that the hill is generated in upper part of the trench by increasing volume of the PSG layer at the wet etching process which forms the trench. Namely, according to use the PSG layer as the first sacrificial layer, the upper surface of the TEOS layer used as the second sacrificial layer is not even after all process is completed. If the bottom electrode is made by using the uneven hole for capacitor, it is not possible to produce the bottom electrode which has a stable shape.

For solving this problem, chemical mechanical polishing CMP is further performed, but this process induces other problem that additional cost and time for producing the capacitor is increased.

FIG. 5 is an exemplary diagram of an electron microscope photo presenting problem of fabricating the conventional capacitor in accordance with the advanced prior art. After making the trench, there are partially generated the hill on the trench. (Referred as B section)

### SUMMARY OF INVENTION

It is, therefore, an object of the present invention to provide method of fabricating a capacitor for improving reliability of a producing process and reducing production costs by forming a bottom electrode of the capacitor in stable shape.

In accordance with an aspect of the present invention, there is provided the method for fabricating the capacitor for a semiconductor device including the step of: forming a sacrificial layer in the height of capacitor on the substrate so that a etch rate becomes lower if it's height becomes higher; forming a trench by selectively eliminating the sacrifice layer in manner of wet etch process; forming a bottom electrode in the trench; eliminating the sacrificial layer; forming a dielectric thin film on the bottom electrode; and forming the top electrode on the dielectric thin film.

### BRIEF DESCRIPTION OF THE DRAWINGS

The above and other objects and features of the present invention will become apparent from the following description of preferred embodiments taken in conjunction with the accompanying drawings, in which:

FIGS. 1A to 1B are sectional views presenting a conventional method of fabricating a cylinder type capacitor in accordance with the prior art;

FIG. 2 is an exemplary diagram of an electron microscope photo presenting problem of fabricating the capacitor shown in FIGS. 1A to 1B;

FIG. 3A and FIG. 3B are a sectional views presenting another conventional method of fabricating a cylinder type capacitor;

FIGS. 4A and 4B are exemplary diagrams of electron microscope photos presenting a cross section of a trench in accordance with the prior art;

FIG. 5 is an exemplary diagram of an electron microscope photo presenting problem of fabricating the capacitor shown in FIGS. 4A to 4B;

FIG. 6A to FIG. 6C are sectional views presenting method of fabricating a cylinder type capacitor in accordance with an preferred embodiment of the present invention; and

FIG. 7 is a table composed of several graphs presenting a wet etch rate and a dep rate of a TEOS layer in response to process conditions.

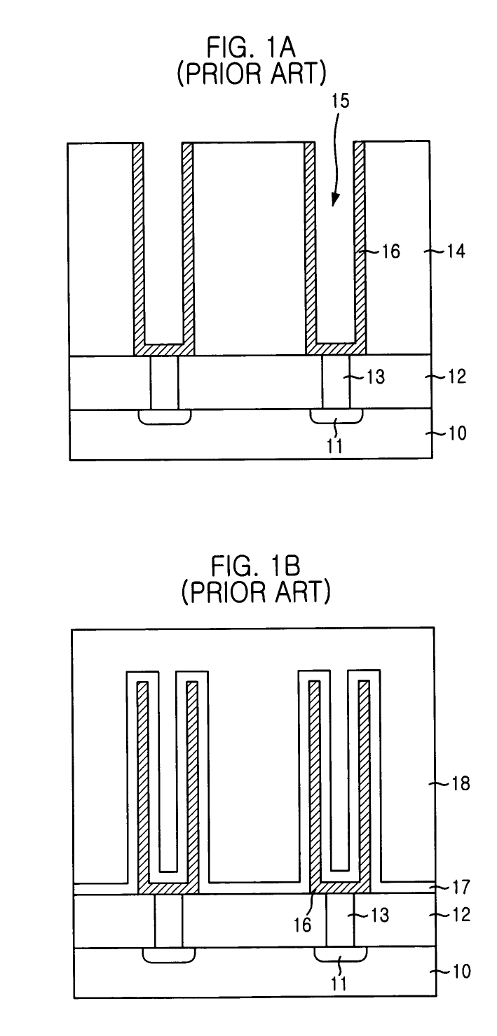

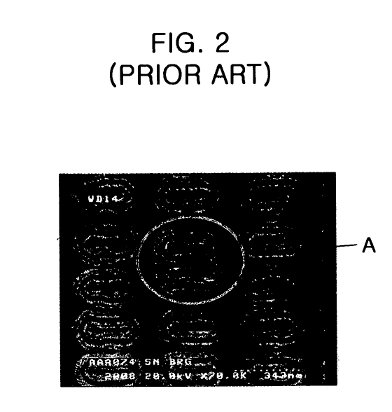

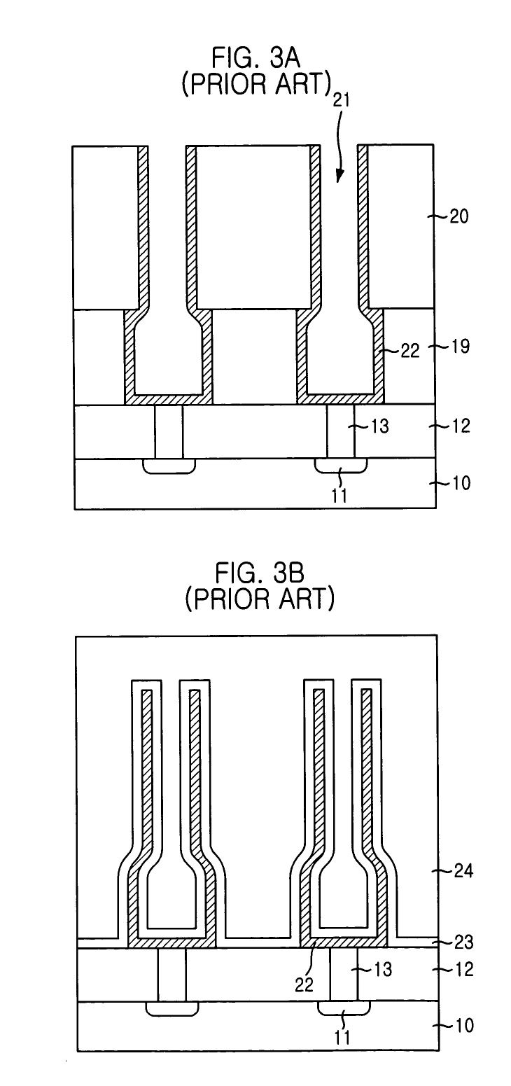

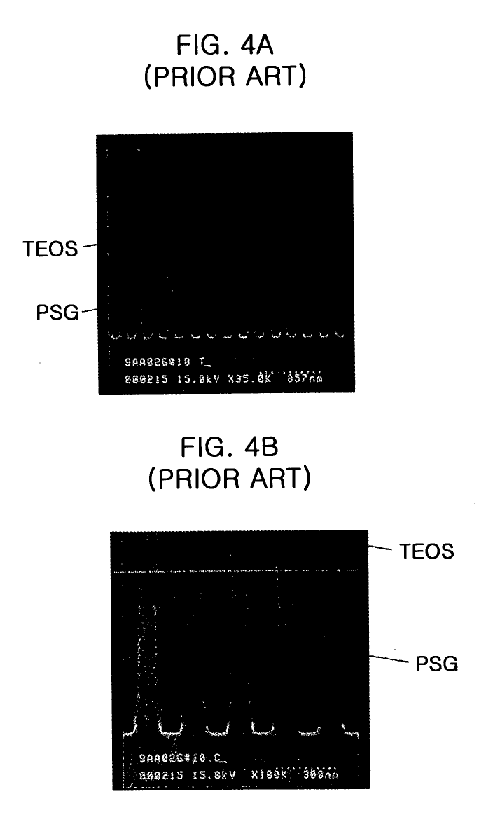

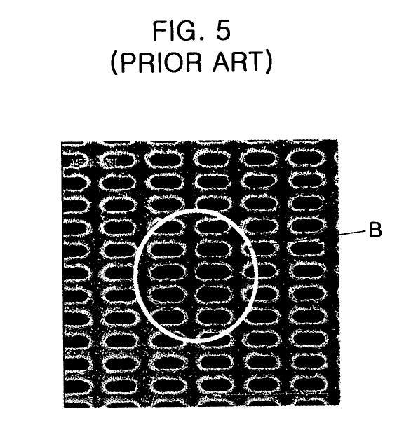

### DETAILED DESCRIPTION OF THE INVENTION

Hereinafter, a method of fabricating a capacitor in a semiconductor device according to the present invention will be described in detail referring to the accompanying drawings.

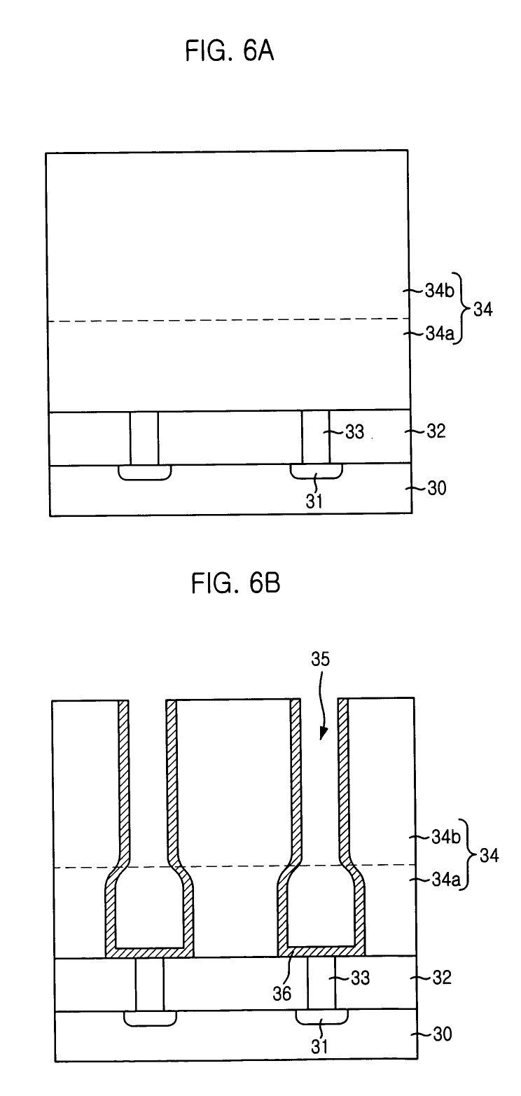

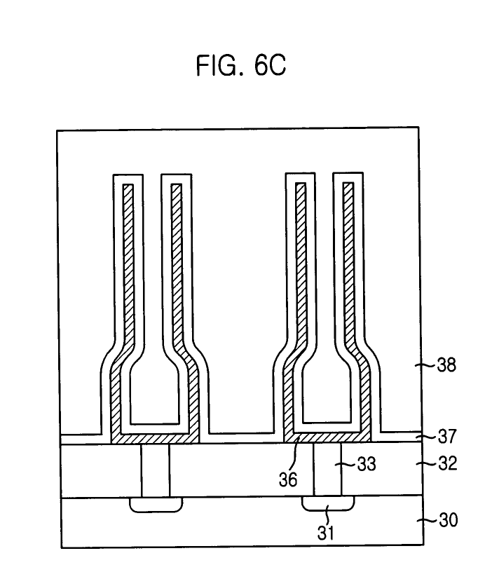

FIG. 6A to FIG. 6C are sectional views presenting method of fabricating a cylinder type capacitor in accordance with an preferred embodiment of the present invention.

As shown in FIG. 6A, an active area 31 is formed in a substrate 30. After an inter-insulation film 32 is formed on a substrate 30, a contact trench is formed for contacting the active area 31 of the substrate 30 through the inter-insulation film 32. The contact trench is buried by a conductive metal to form a contract plug 33. The inter-insulation film 32 is formed by using an oxide film or a thermal oxide film. The oxide film is made of a material selected from the group of undoped-silicate glass USG, phosphor-silicate glass PSG, boro-phospho-silicate glass BPSG, high density plasma HDP, spin on glass SOG, and tetra ethyl ortho silicate TEOS. The thermal oxide film is formed by oxidizing the silicon substrate in temperature ranging from about 600° C. to about 1100° C.

The sacrificial layer 34 is formed of the TEOS layer in size ranging from about 1000 Å to about 25000 Å by using the plasma enhance CVD.

The TEOS layers are formed by the two processes. A first TEOS layer 34a is made in the process condition for equalizing the TEOS layer 34a with the PSG layer in view of physical property. A second TEOS layer 34b is made in the typical process condition. A single TEOS layer can be also used for two layer 34a and 34b

If there is occurred variation of the process when the sacrifice layer is formed by the plasma enhanced CVD, the sacrifice layer is deposed by controlling the etching select ratio, but, in the present embodiment, the TEOS layer is used at the process.

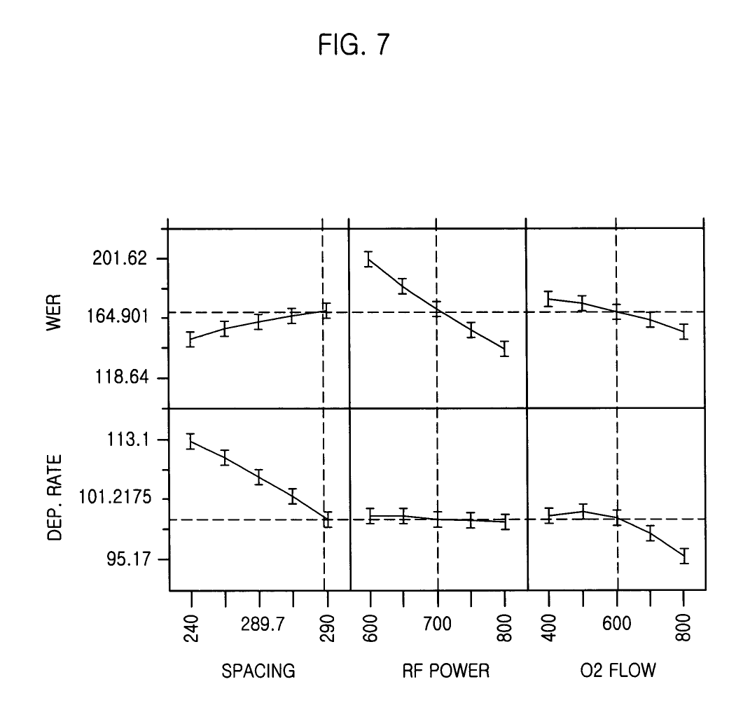

FIG. 7 is a table which is composed of several graphs presenting a wet etch rate and a dep rate of a TEOS layer in response to process conditions. As shown, the wet etch rate is varied in response to a RF power, an O₂ flow, a spacing between the substrate and the shower head.

If these conditions are simultaneously controlled, the TEOS layer has the wet etch rate whose maximum value is at least three times of it's minimum value. Namely, if the RF power is low, the O2 flow is little, and the spacing between the substrate and the shower head is narrow, the wet etch rate of the TEOS layer is high; otherwise, the wet etch rate of the TEOS layer is low.

Thus, when the TEOS layer used as the sacrifice layer 34 is formed, the first TEOS layer 34a is formed by controlling the process condition so that it's wet etch rate is high, and the second TEOS layer 34b is formed so that it's wet etch rate is low. Then, if the trench is formed, lower part of the trench is wide and upper part of the trench is narrow.

Herein, the first TEOS layer 34a is formed in thickness ranging from about 3000 Å to about 15000 Å and the second TEOS layer 34b is formed in thickness ranging from about 5000 Å to about 20000 Å.

In addition, if the sacrifice layer 34 is deposed by at least three steps, the deposed TEOS layer can be deposed so that it's wet etch rate is diversified.

As shown in FIG. 6B, the trench 35 is formed by selectively eliminating the sacrificial layer to expose the contact plug 33. The bottom electrode 35 is formed inside the trench 35, being buried by the conductive material. The bottom electrode 35 can be made of silicon, tungsten, tungsten nitride, iridium, iridium oxide, ruthenium, ruthenium oxide, platinum, titanium nitride, and so on.

As shown in FIG. 6C, the sacrificial layer 34 is eliminated by the wet etching process. The dielectric thin layer 37 is formed on the bottom electrode 36 and the top electrode 38 is formed on the dielectric thin layer 37.

If the capacitor is produced by the above described manner, the capacitor is more stably formed by using one TEOS layer when it is compared with the capacitor which has the sacrifice layer formed by two processes using the PSG and TEOS layers according to the prior art. In addition, the hill is not generated because the PSG layer which generates the hill by absorbing water at the wet etching process is not used at the process.

While the present invention has been described with respect to the particular embodiment, it will be apparent to those skilled in the art that various changes and modification may be made without departing from the spirit and scope of the invention as defined in the following claims.

What is claimed is:

1. A method of fabricating a capacitor for a semiconductor device, comprising the step of:
a) forming a sacrificial layer in the height of capacitor on the substrate so that a etch rate becomes lower if it's height becomes higher;
b) forming a trench by selectively eliminating the sacrifice layer in manner of wet etch process;
c) forming a bottom electrode in the trench;
d) eliminating the sacrificial layer;
e) forming a dielectric thin film on the bottom electrode; and
f) forming the top electrode on the dielectric thin film.

2. The method of fabricating the capacitor as recited in claim 1, wherein the sacrificial layer is a TEOS layer.

3. The method of fabricating the capacitor as recited in claim 2, wherein the sacrifice layer is formed in response to a RF power, an O₂ flow, and a spacing between the substrate and the shower head, and a upper portion of the sacrifice layer has a higher wet etching rate than a lower portion of the sacrifice layer does.

4. The method of fabricating the capacitor as recited in claim 3, wherein the sacrifice layer is deposed in thickness ranging from about 10000 Å to about 25000 Å.
